(19) United States
(12) Patent Application Publication
(10) Pub. No.: US 2005/0074688 A1
(43) Pub. Date: Apr. 7, 2005

(54) Bottom antireflective coatings

(76) Inventors: Medhat A. Toukhy, Flemington, NJ (US); Joseph E. Oberlander, Phillipsburg, NJ (US)

Correspondence Address: CLARIANT CORPORATION;ATTENTION; INDUSTRIAL PROPERTY DEPT., 70 MEISTER AVENUE, SOMERVILLE, NJ, 08876, US

(21) Appl. No.: 10/677,318

(22) Filed: Oct. 3, 2003

(51) Int. Cl. G03F 7/00

(52) U.S. Cl. 430/270.1; 430/330; 430/9; 430/14

(57) ABSTRACT

The present invention relates to bottom antireflective coatings.

The present invention relates to bottom antireflective coatings.

### BACKGROUND OF THE INVENTION

As electronic devices become smaller, there is a continuing desire in the electronics industry to increase the circuit density in electronic components, for example, integrated circuits, circuit boards, multichip modules, chip test devices, and the like without degrading electrical performance, for example, crosstalk or capacitive coupling, and also to increase the speed of signal propagation in these components.

Photoresists play an integral part in the development of these electronic components. Photoresists are photosensitive films used for transfer of an image to a substrate. A coating layer of a photoresist is formed on a substrate, such as a dielectric layer, and the photoresist layer is then exposed through a photomask (reticle) to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or cross-link in a reaction between a photoactive compound and polymerizable reagents of the photoresist composition.

Consequently, the exposed coating portions are rendered less soluble in a developer solution than unexposed portions. For a positive-acting photoresist, exposed portions are rendered more soluble in a developer solution while areas not exposed remain comparatively less developer soluble. Negative and positive photoresist compositions are well known to the art.

In the manufacture of electronic devices, reflection of actinic radiation during exposure of the photoresist is detrimental to fine feature formation. Reflection of actinic radiation, such as from the layer underlying the photoresist, often poses limits on resolution of the image patterned in the photoresist layer. Reflection of radiation from the substrate/photoresist interface can produce variations in the radiation intensity in the photoresist during exposure, resulting in non-uniform photoresist linewidth upon development. Radiation also can scatter from the substrate/photoresist interface into regions of the photoresist where exposure is not intended, again resulting in linewidth variations. The amount of scattering and reflection will typically vary from region to region, resulting in further linewidth non-uniformity.

Reflection of activating radiation also contributes to what is known in the art as the “standing wave effect.” To eliminate the effects of chromatic aberration in exposure equipment lenses, monochromatic or quasi-monochromatic radiation is commonly used in photoresist projection techniques. Due to radiation reflection at the photoresist/substrate interface, however, constructive and destructive interference is particularly significant when monochromatic or quasi-monochromatic radiation is used for photoresist exposure. In such cases the reflected light interferes with the incident light to form standing waves within the photoresist. In the case of highly reflective substrate regions, the problem is exacerbated since large amplitude standing waves create thin layers of underexposed photoresist at the wave minima. The underexposed layers can prevent complete photoresist development causing edge acuity problems in the photoresist profile. The time required to expose the photoresist is generally an increasing function of photoresist thickness because of the increased total amount of radiation required to expose an increased amount of photoresist. However, because of the standing wave effect, the time of exposure also includes a harmonic component which varies between successive maximum and minimum values with the photoresist thickness. If the photoresist thickness is non-uniform, the problem becomes more severe, resulting in variable linewidths.

With recent trends towards high-density semiconductor devices, there is a movement in the industry to shorten the wavelength of exposure sources to deep ultraviolet (DUV) light (300 nm or less in wavelength), KrF excimer laser light (248 nm), ArF excimer laser light (193 nm), F₂ excimer laser (157 nm), electron beams and soft x-rays. The use of shortened wavelengths of light for imaging a photoresist coating has generally resulted in increased reflection from the upper resist surface as well as the surface of the underlying substrate, thus exacerbating the problems of reflection from a substrate surface.

Radiation reflection problems have been addressed by a variety of means, such as the addition of certain dyes to photoresist compositions, the dyes absorbing radiation at or near the wavelength used to expose the photoresist. Conventionally, a radiation absorbing layer either interposed between the substrate surface and the photoresist coating layer, called a bottom antireflective coating or BARC, can be used to reduce the problem of reflection of actinic radiation. Bottom antireflective coatings provide the best solution for the elimination of reflectivity. The bottom antireflective coating is applied on the substrate and then a layer of photoresist is applied on top of the antireflective coating. The photoresist is exposed imagewise and developed. The antireflective layer can then be removed either by dry etching or developed by aqueous alkaline solution. An example of a bottom antireflective coating which is developable by aqueous alkaline solution is found in U.S. patent application Ser. No. 10/042,532, filed Jan., 9, 2002, entitled Positive-Working Photoimageable Bottom Antireflective Coating, the contents of which are hereby incorporated herein by reference. Conventional BARCs, which can be removed by dry etching, are well known to those skilled in the art. Examples include those disclosed in U.S. Pat. Nos. 6,329,117; 6,277,750; 6,042,992; 6,524,708; 6,512,084; 6,432,611; 6,403,152; 6,399,686; 6,391,472; 6,323,3106,602,652; 6,599,951; 6,596,405; 6,576,681; 6,528,235; 6,503,689; 6,261,743; 6,033,830; 5,939,236; 5,932,389; 5,886,102; 5,861,231; 5,851,738; 5,851,730; 5,702,611; and 5,635,333, the contents of which are hereby incorporated by reference herein.

One issue facing the use of bottom antireflective coatings is the solubility of the components of the antireflective coating in the solvent of the particular photoresist composition to be used (also known as the casting solvent of the photoresist). If components in the antireflective coating are soluble in the solvent of the photoresist composition, there is the opportunity for intermixing at the antireflective coating-photoresist interface layer of the antireflective coating components and the photoresist components. This intermixing affects the thickness of the antireflective coating and as such, its ability to evenly absorb reflected actinic radiation, resulting in undercutting or poor footing. This in turn renders the features formed to be of poor quality.

It is possible to develop polymers for bottom antireflective coating which are not soluble in the solvent of the photoresist composition (see, for example, in U.S. patent application Ser. No. 10/042,532, filed Jan. 9, 2002, referenced above). Conventional BARCs are typically baked at high temperatures to crosslink the polymer therein prior to application of the photoresist. However, other components within the antireflective coating, for example, acid generators and bases, may also migrate into the solvent of the photoresist composition at the antireflective coating-photoresist interface, causing uneven cure of the antireflective coating and/or the photoresist.

It has been found that if the bottom antireflective coating contains a base which is not soluble in the solvent of the photoresist composition, the integrity of the bottom antireflective coating can be maintained, resulting in good photoresist film formation and good features.

### SUMMARY OF THE INVENTION

The present invention relates to an antireflective coating composition useful with a photoresist composition where the antireflective coating composition comprises at least one base which is not soluble in a solvent of the photoresist composition. The base has a solubility of less than or equal to 0.2 wt. % in the solvent of the photoresist composition, preferably has a solubility of less than or equal to 0.15 wt. % in the solvent of the photoresist composition, and more preferably has a solubility of less than or equal to 0.1 wt. % in the solvent of the photoresist composition. The antireflective coating composition, preferably a bottom antireflective coating, can further comprise one or more components selected from polymers, solvents, photoacid generators, dyes and surface active agents, and the like. The use and types of these additional components are well known to those skilled in the art.

The present invention also relates to a multilayered structure comprising (a) an antireflective coating; and (b) a photoresist coating formed on the antireflective coating, wherein the antireflective coating comprises at least one base that is not soluble in a solvent of the photoresist composition. The present invention also relates to a multilayered structure comprising (a) a substrate; (b) an antireflective coating formed on top the substrate; and (c) a photoresist coating formed on the antireflective coating, wherein the antireflective composition comprises at least one base that is not soluble in a solvent of the photoresist composition.

The present invention also relates to a method of forming an antireflective coating layer comprising the step of coating a substrate with an antireflective composition comprising at least one base that is not soluble in a solvent of a photoresist composition.

The present invention also relates to a method of making a multilayered structure comprising applying an antireflective coating which comprises at least one base that is not soluble in a solvent of a photoresist composition to a substrate, soft-baking the antireflective coating, and then applying a photoresist composition over the coating. The method can also further comprise exposing the photoresist composition to actinic radiation, and then the exposed coated wafer is then post-exposure baked.

The antireflective coating can contain more than one base, provided at least one base is not soluble in the solvent of the photoresist composition. The amount of base that is not soluble in the solvent of the photoresist composition is generally present in an amount of from about 0.001 to about 15 wt %, preferably from about 0.001 to about 10 wt %, based on the solids of the antireflective coating composition.

Examples of bases that are not soluble in typical solvents of photoresist compositions include, for example, optionally substituted aminophylline, optionally substituted purine, optionally substituted 2,6-diaminopurine, optionally substituted 6-(dimethylamino)purine, optionally substituted xanthine, optionally substituted guanine, optionally substituted hypoxanthine, optionally substituted adenine, optionally substituted caffeine, optionally substituted theophylline, optionally substituted theobromine, optionally substituted pyrmidines, optionally substituted cytosine, optionally substituted cytisine, optionally substituted uracil, optionally substituted thymine, optionally substituted azapyridines, optionally substituted 4-benzimidazioles, optionally substituted 8-azaguanines, optionally substituted 2-hydroaminoazines, and mixtures thereof.

### DETAILED DESCRIPTION OF THE INVENTION

The present invention relates to an antireflective coating composition useful with a photoresist composition where the antireflective coating composition comprises at least one base which is not soluble in a solvent of the photoresist composition. The base has a solubility of less than or equal to 0.2 wt. % in the solvent of the photoresist composition, preferably has a solubility of less than or equal to 0.15 wt. % in the solvent of the photoresist composition, and more preferably has a solubility of less than or equal to 0.1 wt. % in the solvent of the photoresist composition. The antireflective coating composition, preferably a bottom antireflective coating, can further comprise one or more components selected from polymers, solvents, photoacid generators, dyes and surface active agents, and the like. The use and types of these additional components are well known to those skilled in the art.

The present invention also relates to a multilayered structure comprising (a) an antireflective coating; and (b) a photoresist coating formed on the antireflective coating, wherein the antireflective coating comprises a base that is not soluble in a solvent of the photoresist coating. The present invention also relates to a multilayered structure comprising (a) a structure; (b) an antireflective coating formed on top the substrate; and (c) a photoresist coating formed on the antireflective coating, wherein the antireflective coating comprises a base that is not soluble in a solvent of the photoresist coating.

The present invention also relates to a method of forming an antireflective coating layer comprising the step of coating a substrate with an antireflective composition comprising a base that is not soluble in a solvent of a photoresist coating.

The present invention also relates to a method of forming an antireflective coating layer comprising the step of disposing on a substrate an antireflective composition comprising a base that is not soluble in a solvent of a photoresist coating.

The present invention also relates to a method of making a multilayered structure comprising applying an antireflective coating which comprises a base that is not soluble in a solvent of a photoresist composition to a substrate, soft-baking the antireflective coating, and then applying a photoresist composition over the coating. The method can also further comprise exposing the photoresist composition to actinic radiation, and then the exposed coated wafer is then post-exposure baked.

The antireflective coating can contain more than one base, provided at least one base is not soluble in the solvent of the photoresist composition. The amount of base that is not soluble in the solvent of the photoresist composition is generally present in an amount of from about 0.001 to about 15 wt %, preferably from about 0.001 to about 10 wt %, based on the solids of the antireflective coating composition.

Examples of bases that are not soluble in typical solvents of photoresist compositions include, for example, optionally substituted aminophylline, optionally substituted purine, optionally substituted 2,6-diaminopurine, optionally substituted 6-(dimethylamino)purine, optionally substituted xanthine, optionally substituted guanine, optionally substituted hypoxanthine, optionally substituted adenine, optionally substituted caffeine, optionally substituted theophylline, optionally substituted theobromine, optionally substituted pyrmidines, optionally substituted cytosine, optionally substituted cytisine, optionally substituted uracil, optionally substituted thymine, optionally substituted azapyridines, optionally substituted 4-benzimidazioles, optionally substituted 8-azaguanines, optionally substituted 2-hydroaminoazines, and mixtures thereof.

Typical photoresist compositions use propylene glycol monomethyl ether acetate as the casting solvent. Thus, bases which are considered not soluble in propylene glycol monomethyl ether are useful in the present invention. Of course, should the photoresist composition use another solvent, for example, propylene glycol monomethyl ether or ethyl lactate, the base for the antireflective coating should not be soluble in that solvent used in the photoresist composition. Those skilled in the art will also appreciate the typical formulations that comprise photoresist compositions.

An example of a base that is considered not soluble in the typical casting solvent for photoresist is aminophylline. Aminophylline is theophylline with ethylenediamine with a molecular formula of (C₇H₈N₄O₂)₂.C₂H₄(NH₂)₂.2H₂O (See Merck Index 11^{th} Ed., 1989 (substance no. 477, page 76). Theophylline has the following structure:

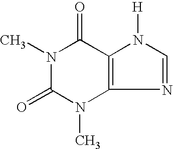

Theophylline broadly falls into the general class of compounds called purine which has the general structure 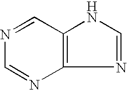
which in itself is generally within the general structure of pyrimidine, which has the structure

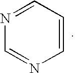

With these general structures, there are for example other compounds that could be considered not soluble in typical casting solvents of photoresists include, for example, optionally substituted aminophylline, optionally substituted purine, optionally substituted 2,6-diaminopurine, optionally substituted 6-(dimethylamino)purine, optionally substituted xanthine, optionally substituted guanine, optionally substituted hypoxanthine, optionally substituted adenine, optionally substituted caffeine, optionally substituted theophylline, optionally substituted theobromine, optionally substituted pyrmidines, optionally substituted cytosine, optionally substituted cytisine, optionally substituted uracil, optionally substituted thymine, optionally substituted azapyridines, optionally substituted 4-benzimidazioles, optionally substituted 8-azaguanines, optionally substituted 2-hydroaminoazines, and mixtures thereof. Those in the art will appreciate that the substituents placed on the base molecules are those that do not materially affect the base molecules and can include, for example, alkyl, amino, hydroxyl, nitro, etc and the like.

Several bases were evaluated for solubility in propylene glycol monomethyl ether acetate, the most commonly used solvent in photoresist compositions. A 0.2 wt. % solution of each base was made with propylene glycol monomethyl ether acetate in glass vials. The vials were then placed on a shaker and allowed to shake overnight (˜20 hours) at room temperature. The vials were then visually inspected. If the vials were clear without any haze, cloudiness or solids or crystals at the bottom of the vial, then the base was considered soluble in propylene glycol monomethyl ether acetate. If the vials had haze, cloudiness or solids or crystals at the bottom of the vial, the base was considered not soluble in propylene glycol monomethyl ether acetate. For those vials which contained base at 0.2 wt. % and were considered not soluble, additional propylene glycol monomethyl ether acetate was added to dilute the solution to 0.15 wt. %, or 0.10 wt. %. The diluted vials were then evaluated as discussed above. No further dilutions were made beyond 0.10 wt. %. The results are shown in Table 1 below.

TABLE 1

| | 0.2 wt. % in | 0.1 wt. % in |
|---|---|---|
| Base | PGMEA¹ | PGMEA |
| Aminophylline | Not soluble | Not soluble |
| 8-Chlorotheophyllline | Not soluble | Not soluble |
| Theophylline | Not soluble | Soluble |
| Caffeine | Not soluble² | Soluble |
| 6-(Dimethylamino)purine | Not soluble | Soluble |
| Guanine | Not soluble | Not soluble |
| Purine | Not soluble | Not soluble |
| Adenine | Not soluble | Not soluble |
| 2,6-Diaminopurine | Not soluble | Not soluble |

¹propylene glycol monomethyl ether acetate
²soluble at 0.15 wt. % in PGMEA

Thus, bases which have a solubility of less than or equal to 0.2 wt. % in the solvent of the photoresist composition, preferably having a solubility of less than or equal to 0.15 wt. % in the solvent of the photoresist composition, and more preferably having a solubility of less than or equal to 0.1 wt. % in the solvent of the photoresist composition are suitable for use with the present invention.

The polymers, photoacid generators and other ancillary materials (such as solvents, dyes and surface active agents) typically used in antireflective coatings are well known to those skilled in the art. Those in the art will appreciate that most, if not all, materials used in the antireflective coating should not be soluble in the solvent of the top layer resist prior to application of the top layer resist. One example of such a polymer is found in Ser. No. 10/042,532, filed Jan. 9, 2002, entitled Positive-Working Photoimageable Bottom Antireflective Coating referenced above. Examples of other polymers used in conventional antireflective coatings can be found in, for example, U.S. Pat. Nos. 6,329,117; 6,277,750; 6,042,992; 6,524,708; 6,512,084; 6,432,611; 6,403,152; 6,399,686; 6,391,472; 6,323,3106,602,652; 6,599,951; 6,596,405; 6,576,681; 6,528,235; 6,503,689; 6,261,743; 6,033,830; 5,939,236; 5,932,389; 5,886,102; 5,861,231; 5,851,738; 5,851,730; 5,702,611; and 5,635,333 referenced above. Examples of photoacid generators include, but are not limited to, those known in the art, such as those disclosed in, for example, U.S. Pat. No. 5,731,386, U.S. Pat. No. 5,880,169, U.S. Pat. No. 5,939,236, U.S. Pat. No. 5,354,643, U.S. Pat. No 5,716,756, DE 3,930,086, DE 3,930,087, German Patent Application P 4,112,967.9, F. M. Houlihan et al., J. Photopolym. Sci. Techn., 3:259 (1990); T. Yamaoka et al., J. Photopolym. Sci. Techn., 3:275 (1990)), L. Schlegel et al., J. Photopolym. Sci. Techn., 3:281 (1990) and M. Shirai et al., J. Photopolym. Sci. Techn., 3:301 (1990), and incorporated herein by reference.

### EXAMPLES

Table 2 shows several antireflective coating formulations containing different levels of bases. For this experiment, base A is aminophylline, which is considered an insoluble base in the solvent of the photoresist (in this experiment, propylene glycol monomethyl ether acetate) but soluble in the solvent of the antireflective coating (in this experiment, 4-hydroxy-4-methyl-2-pentanone); base B is tridodecylamine, which is soluble in,both the solvent of the photoresist (in this experiment, propylene glycol monomethyl ether acetate) and the solvent of the antireflective coating (in this experiment, 4-hydroxy-4-methyl-2-pentanone). The bases were evaluated alone or as mixtures in the antireflective coatings. The antireflective coatings were prepared using a co-polymer of benzyl methacrylate—mevalonic lactone methacrylate. The photoacid generator (PAG) was triphenylsulfonium nonaflate, and the aforementioned base(s) and 4-hydroxy-4-methyl-2-pentanone as the solvent completed the antireflective coating formulations. The PAG content was kept at 1.7 wt. % of total solids of the antireflective coating formulations and the antireflective coating formulations were 1.65% total solids.

AZ® T-444, a 193 nm chemically amplified resist prepared and applied from propylene glycol monomethyl ether acetate was used as the top layer. Each of the antireflective coating formulations was applied on silicon wafer, spun coated at 3000 rpm to form a 30 nm film and baked at 110° C. for 60 seconds. The top layer resist was then applied on each of the antireflective coating formulations to give a top layer film thickness of about 330 nm. The coated wafer was then baked at 115° C. for 60 seconds. Each wafer was then exposed to 193 nm radiation through a patterned mask and post exposure baked at 130° C. for 60 seconds. The resist and the antireflective coating formulation on each wafer were then developed in an aqueous solution of 0.26N tetramethylammonium hydroxide for 30 seconds in puddle mode. The resist was examined at ˜30 to 33 mJ/cm² dose to size and the antireflective coating (BARC) clearing was reported. The resist undercut was also reported.

TABLE 2

| Ex- | Total | Ratio of | Performance: |
|---|---|---|---|
| ample | base wt % | base A to B | At resist dose to size 1:1 (0.18 μm) |
| Ex. 1 | 0.303 | 100.0:0 | BARC cleared with resist undercut |
| Ex. 2 | 0.5976 | 100.0:0 | BARC cleared with scum/foot |
| Ex. 3 | 0.9178 | 100.0:0 | BARC did not clear |
| Ex. 4 | 0.5035 | 100.0:0 | BARC cleared, no scum |
| Ex. 5 | 1.7587 | 22.2:77.8 | BARC cleared with scum/foot |
| Ex. 6 | 1.6362 | 10.38:89.62 | BARC cleared with scum/foot |
| Ex. 7 | 1.381 | 20.1:79.9 | BARC cleared with scum/foot |
| Ex. 8 | 1.0472 | 30.55:69.44 | BARC cleared with scum/foot |
| Ex. 9 | 1.4084 | 8.95:91.05 | BARC did not clear |
| Ex. 10 | 1.1466 | 12.3:87.7 | BARC cleared with resist undercut |
| Ex. 11 | 1.188 | 25.57:74.43 | BARC cleared with scum/foot |
| Ex. 12 | 1.395 | 32.7:67.3 | BARC did not clear completely (foot) |
| Ex. 13 | 1.9276 | 25.85:74.15 | BARC did not clear |
| Ex. 14 | 0.7765 | 48.0:52.0 | BARC cleared with resist undercut |
| Ex. 15 | 0.7944 | 61.0:39.0 | BARC cleared, no scum |
| Ex. 16 | 1.3887 | 0:100.0 | BARC cleared with resist undercut |
| Ex. 17 | 0.6072 | 0:100.0 | BARC cleared With resist undercut |

The data from Table 2 show that when the antireflective coating contains a base that is not soluble in the top layer resist solvent (whether that base is used alone or used together with a base that is soluble in the top layer resist solvent), the performance is better than those antireflective coatings which contain only a base that is soluble in the top layer resist solvent.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. An antireflective coating composition useful with a photoresist composition comprising at least one base which is not soluble in a solvent of the photoresist composition.

2. The antireflective coating composition of claim 1 wherein the base has a solubility of less than or equal to 0.2 wt. % in a solvent of the photoresist composition.

3. The antireflective coating composition of claim 1 wherein the base has a solubility of less than or equal to 0.15 wt. % in a solvent of the photoresist composition.

4. The antireflective coating composition of claim 1 wherein the base has a solubility of less than or equal to 0.1 wt. % in a solvent of the photoresist composition.

5. The antireflective coating composition of claim 1 wherein only one base which is not soluble in a solvent of the photoresist composition is present.

6. The antireflective coating composition of claim 1 wherein the base is present in an amount of from about 0.001 to about 15 wt % based on the solids of the antireflective coating composition.

7. The antireflective coating composition of claim 6 wherein the base is present in an amount of from about 0.001 to about 10 wt % based on the solids of the antireflective coating composition.

8. The antireflective coating composition of claim 1 which further comprises at least one base which is soluble in a solvent of the photoresist composition.

9. The antireflective coating composition of claim 1 which further comprises one or more components selected from polymers, crosslinking materials, solvents, photoacid generators, dyes and surface active agents.

10. The antireflective coating composition of claim 1 wherein at least one base which is not soluble in a solvent of the photoresist composition is selected from optionally substituted aminophylline, optionally substituted purine, optionally substituted 2,6-diaminopurine, optionally substituted 6-(dimethylamino)purine, optionally substituted xanthine, optionally substituted guanine, optionally substituted hypoxanthine, optionally substituted adenine, optionally substituted caffeine, optionally substituted theophylline, optionally substituted theobromine, optionally substituted pyrmidines, optionally substituted cytosine, optionally substituted cytisine, optionally substituted uracil, optionally substituted thymine, optionally substituted azapyridines, optionally substituted 4-benzimidazioles, optionally substituted 8-azaguanines, optionally substituted 2-hydroaminoazines, and mixtures thereof.

11. An-antireflective coating composition useful with a photoresist composition comprising from about 0:001 to about 15 wt % based on the solids of the antireflective coating composition of at least one base which is not soluble in a solvent of the photoresist composition.

12. The antireflective coating composition of claim 11 comprising from about 0.001 to about 10 wt % based on the solids of the antireflective coating composition of at least one base which is not soluble in a solvent of the photoresist composition.

13. An antireflective coating composition useful with a photoresist composition comprising at least one base which has a solubility of less than or equal to 0.2 wt. % in a solvent of the photoresist composition.

14. The antireflective coating composition of claim 13 wherein the base has a solubility of less than or equal to 0.15 wt. % in a solvent of the photoresist composition.

15. The antireflective coating composition of claim 13 wherein the base has a solubility of less than or equal to 0.1 wt. % in a solvent of the photoresist composition.

16. A multilayered structure comprising:
(a) an antireflective coating formed from the antireflective coating composition of claim 1; and
(b) a photoresist coating formed on top of said antireflective coating.

17. The multilayered structure of claim 14 wherein (a) the antireflective coating is first formed on a substrate.

18. The multilayered structure of claim 17 wherein (a) the antireflective coating is soft-baked prior to forming the photoresist coating on top thereof.

19. The multilayered structure of claim 16 wherein the (a) antireflective coating is developable in an aqueous alkaline developer.

20. The multilayered structure of claim 16 wherein the (a) antireflective coating is removable by dry etch.

21. The multilayered structure of claim 16 wherein for (a) the base has a solubility of less than or equal to 0.2 wt. % in a solvent of the photoresist composition.

22. The multilayered structure of claim 16 wherein for (a) the base has a solubility of less than or equal to 0.15 wt. % in a solvent of the photoresist composition.

23. The multilayered structure of claim 16 wherein for (a) the base has a solubility of less than or equal to 0.1 wt. % in a solvent of the photoresist composition.

24. The multilayered structure of claim 16 wherein for (a) the base is present in an amount of from about 0.001 to about 15 wt % based on the solids of the antireflective coating composition.

25. The multilayered structure of claim 24 wherein the base is present in an amount of from about 0.001 to about 10 wt % based on the solids of the antireflective coating composition.

26. A multilayered structure comprising:
(a) a substrate;
(b) an antireflective coating formed from the antireflective coating composition of claim 1 on top of said substrate; and
(c) a photoresist coating formed on top of said antireflective coating.

27. The multilayered structure of claim 26 wherein for (b) the base has a solubility of less than or equal to 0.2 wt. % in a solvent of the photoresist composition.

28. The multilayered structure of claim 26 wherein for (b) the base has a solubility of less than or equal to 0.15 wt. % in a solvent of the photoresist composition.

29. The multilayered structure of claim 26 wherein for (b) the base has a solubility of less than or equal to 0.1 wt. % in a solvent of the photoresist composition.

30. The multilayered structure of claim 26 wherein for (a) the base is present in an amount of from about 0.001 to about 15 wt % based on the solids of the antireflective coating composition.

31. The multilayered structure of claim 30 wherein the base is present in an amount of from about 0.001 to about 10 wt % based on the solids of the antireflective coating composition.

32. A method for forming an antireflective coating layer comprising the step of coating a substrate with the antireflective coating composition of claim 1.

33. The method of claim 32 wherein for the antireflective coating composition, the base has a solubility of less than or equal to 0.2 wt. % in a solvent of the photoresist composition.

34. The method of claim 32 wherein for the antireflective coating composition, the base has a solubility of less than or equal to 0.15 wt. % in a solvent of the photoresist composition.

35. The method of claim 32 wherein for the antireflective coating composition, the base has a solubility of less than or equal to 0.1 wt. % in a solvent of the photoresist composition.

36. The method of claim 32 wherein for (a) the base is present in an amount of from about 0.001 to about 15 wt % based on the solids of the antireflective coating composition.

37. The method of claim 36 wherein the base is present in an amount of from about 0.001 to about 10 wt % based on the solids of the antireflective coating composition.

38. A method of making a multilayered structure comprising:
(a) applying the antireflective coating composition of claim 1 to a substrate;
(b) soft-baking the coating of step (a); and
(c) applying a photoresist composition to the coating of step (b).

39. The method of claim 38 wherein the antireflective coating is developable in an aqueous alkaline developer.

40. The method of claim 38 wherein the antireflective coating is removable by dry etch.

41. The method of claim 38 wherein for the antireflective coating composition, the base has a solubility of less than or equal to 0.2 wt. % in a solvent of the photoresist composition.

42. The method of claim 38 wherein for the antireflective coating composition, the base has a solubility of less than or equal to 0.15 wt. % in a solvent of the photoresist composition.

43. The method of claim 38 wherein for the antireflective coating composition, the base has a solubility of less than or equal to 0.1 wt. % in a solvent of the photoresist composition.

44. The method of claim 38 wherein for (a) the base is present in an amount of from about 0.001 to about 15 wt % based on the solids of the antireflective coating composition.

45. The method of claim 44 wherein the base is present in an amount of from about 0.001 to about 10 wt % based on the solids of the antireflective coating composition.

46. The method of claim 38 which further comprises the steps of
(d) exposing the photoresist composition to actinic radiation; and
(e) post-exposure baking the exposed coated wafer.
